(19) United States
(12) Patent Application Publication
(10) Pub. No.: US 2026/0181949 A1
(43) Pub. Date: Jun. 25, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Seiichi URAKAWA, Yokkaichi Mie (JP)

(21) Appl. No.: 19/315,388

(22) Filed: Aug. 29, 2025

(30) Foreign Application Priority Data
Dec. 20, 2024 (JP) 2024-225209

(51) Int. Cl. H10D 30/67; H10B 12/00; H10D 30/01

(52) U.S. Cl. CPC H10D 30/6728; H10B 12/33; H10D 30/0318; H10D 30/6755

(57) ABSTRACT

A semiconductor device includes a first electrode, a second electrode provided above the first electrode in a first direction perpendicular to a surface of the first electrode, an oxide semiconductor having a first end in contact with the first electrode and a second end in contact with the second electrode and extending in the first direction, a gate insulating film surrounding a side surface of the oxide semiconductor, and a gate electrode surrounding a side surface of the gate insulating film. The gate electrode includes a recess provided on a surface facing the oxide semiconductor.

### CROSS-REFERENCE TO RELATED APPLICATION

This application is based upon and claims the benefit of priority from Japanese Patent Application No. 2024-225209, filed December 20, 2024, the entire contents of which are incorporated herein by reference.

### FIELD

Embodiments described herein relate generally to a semiconductor device and a method of manufacturing a semiconductor device.

### BACKGROUND

Research and development of a semiconductor device including a transistor where an oxide semiconductor is used for a channel has progressed.

### BRIEF DESCRIPTION OF THE DRAWINGS

FIG. 1 is a block diagram illustrating a configuration example of a memory system including a semiconductor device according to an embodiment.

FIG. 2 is a circuit diagram illustrating a circuit configuration example of a memory cell array of the semiconductor device according to the embodiment.

FIG. 3 is a plan view diagram illustrating a structure of the semiconductor device according to a first embodiment.

FIG. 4 is a cross-sectional diagram illustrating the structure of the semiconductor device according to the first embodiment.

FIG. 5 is another cross-sectional diagram illustrating the structure of the semiconductor device according to the first embodiment.

FIG. 6 is a flowchart illustrating a method of manufacturing the semiconductor device according to the first embodiment.

FIGS. 7-13 are cross-sectional diagrams illustrating process steps of the method of manufacturing the semiconductor device according to the first embodiment.

FIG. 14 is a cross-sectional diagram illustrating a structure of a semiconductor device according to a second embodiment.

FIG. 15 is another cross-sectional diagram illustrating the structure of the semiconductor device according to the second embodiment.

FIGS. 16 and 17 are cross-sectional diagrams illustrating process steps of a method of manufacturing the semiconductor device according to the second embodiment.

FIG. 18 is a cross-sectional diagram illustrating a structure of a semiconductor device according to a third embodiment.

FIG. 19 is another cross-sectional diagram illustrating the structure of the semiconductor device according to the third embodiment.

FIGS. 20-23 are cross-sectional diagram illustrating process steps of a method of manufacturing the semiconductor device according to the third embodiment.

### DETAILED DESCRIPTION

Embodiments provide a semiconductor device with improved transistor characteristics.

In general, according to an embodiment, a semiconductor device includes: a first electrode; a second electrode provided above the first electrode in a first direction perpendicular to a surface of the first electrode; an oxide semiconductor having a first end in contact with the first electrode and a second end in contact with the second electrode and extending in the first direction; a gate insulating film surrounding a side surface of the oxide semiconductor; and a gate electrode surrounding a side surface of the gate insulating film. The gate electrode includes a recess provided on a surface facing the oxide semiconductor.

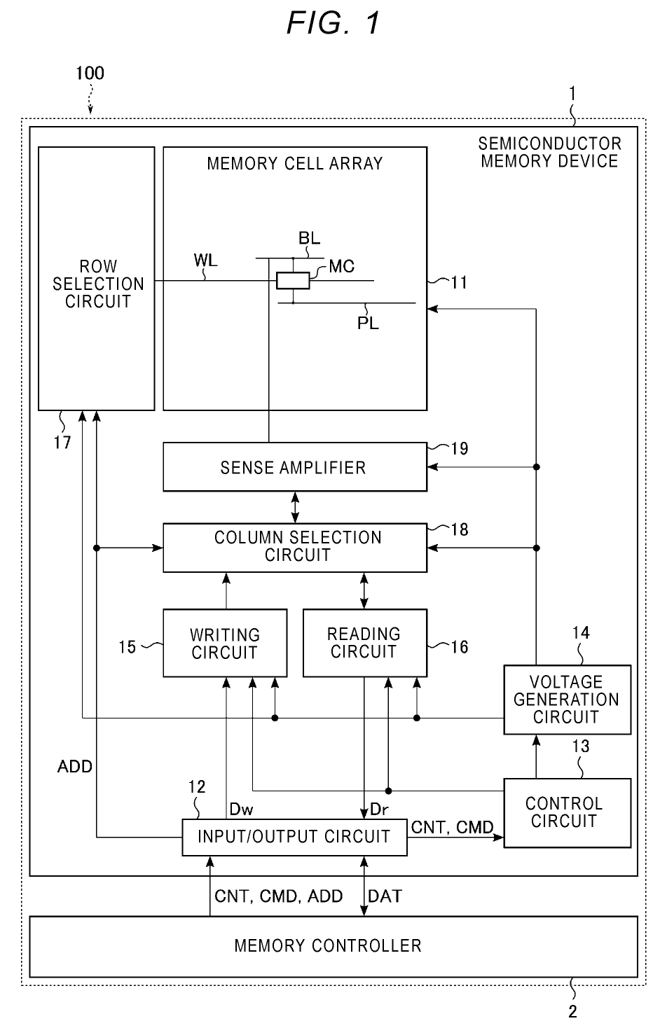

A semiconductor device according to an embodiment and a method of manufacturing the semiconductor device will be described with reference to FIGS. 1 to 23. In the following description, elements having the same function and configuration will be represented by the same reference numerals. In addition, in each of the following embodiments, when components (for example, circuits, wirings, various voltages, and signals) represented by reference numerals ending in numbers/alphabetical letters for distinction do not need to be distinguished from each other, the description (reference numeral) without the last number/alphabetical letter is used. The drawings are schematic, and a relationship between a film thickness and a planar dimension, a ratio between film thicknesses of layers, and the like are different from the actual ones. Accordingly, a specific film thickness or dimension should be determined in consideration of the following description. In addition, the drawings may include portions having different relationships or ratios between dimensions.

### Embodiments

### (1) First Embodiment

A semiconductor device and a method of manufacturing the semiconductor device according to a first embodiment will be described with reference to FIGS. 1 to 13.

(a) Configuration

A configuration of the semiconductor device according to the first embodiment will be described.

(a-1) Memory System

A configuration of a memory system including the semiconductor device according to the present embodiment will be described using FIG. 1. FIG. 1 is a block diagram illustrating an example of the configuration of the memory system including the semiconductor device according to the present embodiment.

A memory system 100 executes a write operation, a read operation, and the like of data according to a command from an external host apparatus (not illustrated) of the memory system 100.

The memory system 100 includes a semiconductor device 1 and a memory controller 2.

(a-1-1) Internal Configuration of Semiconductor Device 1

The semiconductor device 1 is a memory device where a transistor is used for selecting a target memory element of an operation. The semiconductor device 1 stores data, for example, using a capacitor as a memory element. The semiconductor device 1 is, for example, a dynamic random access memory (DRAM). The memory controller 2 controls the semiconductor device 1.

The semiconductor device 1 includes a memory cell array 11, an input/output circuit 12, a control circuit 13, a voltage generation circuit 14, a write circuit 15, a read circuit 16, a row selection circuit 17, a column selection circuit 18, and a sense amplifier 19.

The memory cell array 11 includes a plurality of memory cells MC, a plurality of word lines WL, a plurality of bit lines BL, and a plate line PL. FIG. 1 illustrates one memory cell MC, one word line WL, and one bit line BL. Each of the memory cells MC stores 1-bit data. Each of the memory cells MC connects one corresponding bit line BL among the plurality of bit lines BL to the plate line PL. Each of the memory cells MC is connected to one corresponding word line WL among the plurality of word lines WL. The word line WL is associated with a row. The bit line BL is associated with a column. In the memory cell array 11, one memory cell MC is specified by selecting one row and selecting one column.

The input/output circuit 12 receives a control signal CNT, a command CMD, an address ADD, and data DAT from the memory controller 2. The input/output circuit 12 transmits the data DAT to the memory controller 2. When data is written into the semiconductor device 1, the data DAT is write data Dw. When data is read from the semiconductor device 1, the data DAT is read data Dr.

The control circuit 13 receives the control signal CNT and the command CMD from the input/output circuit 12. The control circuit 13 instructs the write circuit 15 to write the data DAT into the memory cell array 11 based on the control signal CNT and the command CMD. The control circuit 13 instructs the read circuit 16 to read data from the memory cell array 11 based on the control signal CNT and the command CMD. The control circuit 13 instructs the voltage generation circuit 14 to generate various voltages based on the control signal CNT and the command CMD.

The voltage generation circuit 14 generates various voltages used for an operation on the memory cell array 11 based on the instruction of the control circuit 13. The voltage generation circuit 14 supplies the generated voltages to the memory cell array 11, the write circuit 15, the read circuit 16, the row selection circuit 17, the column selection circuit 18, and the sense amplifier 19.

The write circuit 15 executes a process and a control for writing data into the memory cell MC. The write circuit 15 receives the write data Dw from the input/output circuit 12. The write data Dw is data to be written into the memory cell MC as a data write target. The write circuit 15 receives one or more voltages used for a data write operation from the voltage generation circuit 14. The write circuit 15 supplies one or more voltages used for the data write operation to the column selection circuit 18 based on the control of the control circuit 13 and the write data Dw.

The read circuit 16 executes a process and a control for reading data from the memory cell MC. The read circuit 16 receives one or more voltages used for a data read operation from the voltage generation circuit 14. The read circuit 16 determines values of data stored in the memory cell MC using the voltages used for the data read operation based on the control of the control circuit 13. The data of the determined value is supplied to the input/output circuit 12 as the read data Dr.

The row selection circuit 17 receives the address ADD from the input/output circuit 12. The row selection circuit 17 supplies the voltage supplied from the voltage generation circuit 14 to the memory cell array 11. As a result, the row selection circuit 17 sets one word line WL that is associated with a row specified by the address ADD to a selected state.

The column selection circuit 18 receives the address ADD from the input/output circuit 12. The column selection circuit 18 supplies the voltage supplied from the voltage generation circuit 14 to the memory cell array 11. As a result, the column selection circuit 18 sets a bit line BL that is associated with a column specified by the address ADD to a selected state.

The sense amplifier 19 amplifies the voltage of the bit line BL to determine data stored in the memory cell MC as a read target during a data read operation using the voltage received from the voltage generation circuit 14.

(a-1-2) Circuit Configuration of Memory Cell Array

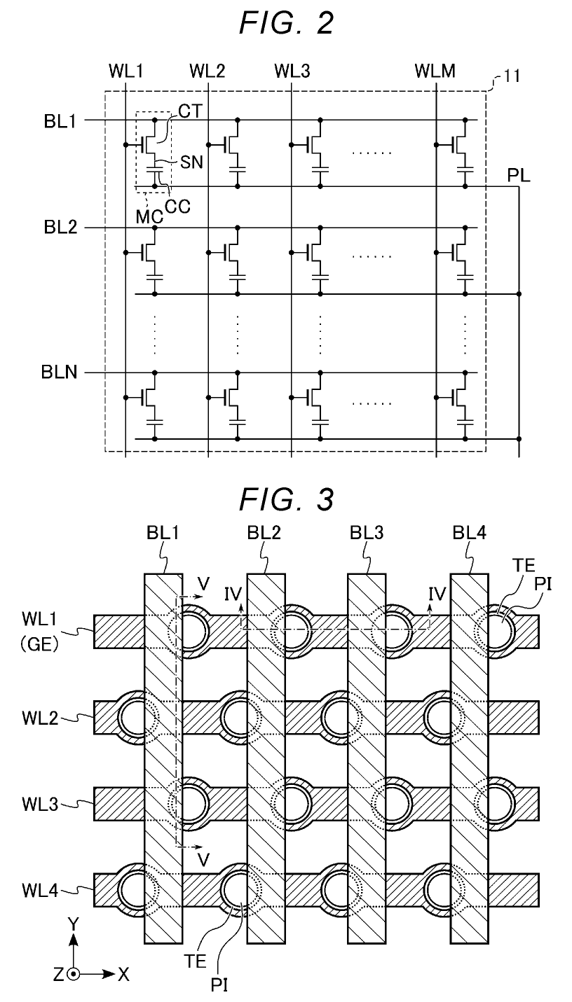

A circuit configuration of the memory cell array 11 of the semiconductor device 1 according to the present embodiment will be described using FIG. 2. FIG. 2 is a circuit diagram illustrating an example of the circuit configuration of the memory cell array 11 of the semiconductor device 1 according to the present embodiment.

The memory cell array 11 includes m word lines WL (WL1, ..., and WLm), n bit lines BL (BL1, ..., and BLn), and a plate line PL. m and n represent positive integers.

Each of the plurality of bit lines BL is connected to m memory cells MC corresponding to one bit line BL among the plurality of memory cells MC. Each of the m memory cells MC corresponding to one bit line BL is connected to, for example, one corresponding word line among the m word lines WL.

Each of the memory cells MC includes a cell capacitor CC and a cell transistor CT.

The cell transistor CT is a switching element (selection element) for selecting a target memory element of an operation. The cell transistor CT is, for example, an n-type metal oxide semiconductor field effect transistor (MOSFET). Hereinafter, one of a source and a drain of the cell transistor CT will also be simply referred to as a first end of the cell transistor CT, and the rest of the source and the drain will also be simply referred to as a second end of the cell transistor CT. The first end of each of the cell transistors CT is connected to one bit line BL associated with the cell transistor CT. A gate of each of the cell transistors CT is connected to one word line WL associated with the cell transistor CT.

A semiconductor forming a part of the cell transistor CT includes a region (channel region) where a channel of a transistor is to be formed. A material of the semiconductor includes an oxide semiconductor. When a material has a configuration A, the material may include unintended impurity different from the configuration A.

The cell capacitor CC is a capacitive element that functions as a memory element. An electrode of a first end of each of the cell capacitors CC is connected to the second end of the cell transistor CT corresponding to the cell capacitor CC. An electrode of a second end of each of the cell capacitors CC is connected to the plate line PL. The cell capacitor CC stores data based on charge stored in a node SN connected to the cell transistor CT. Hereinafter, the node SN that stores the charge of the cell capacitor CC will also be referred to as the storage node SN.

Whether the memory cell MC is in a state where data of "1" is stored or in a state where data of "0" is stored is specified according to the amount of charge stored in the storage node SN. Hereinafter, for example, a state where the storage node SN is charged to a potential that is higher than or equal to the potential of the plate line PL is the state where the memory cell MC stores data of "1". A state where the storage node SN is charged to a potential that is lower than the potential of the plate line PL is the state where the memory cell MC stores data of "0".

In the above-described configuration, in each of the memory cells MC, the cell capacitor CC and the cell transistor CT are connected in series between the bit line BL corresponding to the memory cell MC and the plate line PL.

(a-1-3) Planar Layout of Memory Cell Array

A planar layout of the memory cell array 11 of the semiconductor device 1 according to the present embodiment will be described using FIG. 3. FIG. 3 is a plan view diagram illustrating an example of the planar layout of the memory cell array 11 of the semiconductor device 1 according to the present embodiment. FIG. 3 illustrates, for example, four word lines WL1, ..., and WL4 and four bit lines BL1, ..., and BL4.

In the following description, an X direction is a direction substantially parallel to a substrate of the semiconductor device 1. The X direction corresponds to an extending direction of the word line WL. A Y direction is a direction substantially parallel to the substrate of the semiconductor device 1 and perpendicular to the X direction. The Y direction corresponds to an extending direction of the bit line BL. A Z direction is a direction substantially perpendicular to the substrate. In the Z direction, a side from the substrate toward the memory cell array 11 will be referred to as an upper side. In the Z direction, a side from the memory cell array 11 toward the substrate will be referred to as a lower side. Among two surfaces of one component perpendicular to the Z direction, a surface on the upper side will be referred to as an upper surface, and a surface on the lower side will be referred to as a lower surface. A surface of one component substantially parallel to the Z direction (surface intersecting the X direction and the Y direction) will be referred to as a side surface.

The memory cell array 11 includes a plurality of pillars PI, a plurality of conductors GE, and a plurality of upper electrodes TE associated with the plurality of bit lines BL and the plurality of word lines WL.

Each of the pillars PI functions as, for example, a member of the cell transistor CT. When the cell transistor CT is a vertical transistor, each of the pillars PI includes a semiconductor functioning as a channel region of the cell transistor CT.

In the present embodiment, each of the plurality of conductors GE functions as a gate electrode GE and the word line WL of the cell transistor CT.

FIG. 3 illustrates sets including the pillars PI in four rows. The sets including the pillars PI in the four rows are provided corresponding to the word lines WL1, ..., and WL4, respectively. On each of the rows, the four pillars PI are arranged in the X direction. In each of the sets including the pillars PI in the rows, four pillars PI are arranged substantially at regular intervals in the X direction. Among the sets including the pillars PI in the two rows adjacent to each other in the Y direction, positions of four pillars PI in one row are different from positions of four pillars PI in the rest row in the X direction, respectively. Due to the above-described arrangement, among the sets including the pillars PI in the two rows adjacent to each other in the Y direction, four pillars PI in one row and four pillars PI in the rest row are arranged to be shifted in the X direction. For example, the pillars PI in an odd-numbered row are adjacent to the pillars PI in an even-numbered row in a direction intersecting the X direction and the Y direction.

FIG. 3 illustrates a case where each of the sets including the pillars PI in the four rows includes four pillars PI. The number of rows of the pillars PI and the number of pillars PI in each of the rows are not limited to these numbers. The number of rows of the pillars PI and the number of pillars PI in each of the rows can be appropriately changed.

Each of the pillars PI is connected to the corresponding bit line BL via the upper electrode TE. Each of the plurality of bit lines BL extends in the Y direction. The plurality of bit lines BL are arranged in the X direction. Hereinafter, among the bit line BL1 and the bit line BL4, the bit line BL1 side will be referred to as a first end side in the X direction, and the bit line BL4 side will be referred to as a second end side in the X direction. Each of the bit lines BL is disposed to overlap at least a part of one pillar PI in the set including the pillars PI in each of the rows when seen from the Z direction. Each of the bit lines BL overlaps, for example, the first end side of the pillars PI in the row (in an odd-numbered row) corresponding to the word line WL1 or the word line WL3 in the X direction. Each of the bit lines BL overlaps, for example, the second end side of the pillars PI in the row (in an even-numbered row) corresponding to the word line WL2 or the word line WL4 in the X direction.

Each of the bit lines BL is electrically connected to the pillars PI overlapping the bit line BL. The number of the pillars PI overlapping the bit line BL can be designed to any number according to the number of the word lines WL.

Each of the gate electrodes GE (word lines WL) extends in the X direction. The plurality of gate electrodes GE are arranged in the Y direction. The gate electrode GE is provided to surround the periphery of the pillar PI corresponding to the gate electrode GE when seen from the Z direction. The gate electrode GE faces a side surface of the pillar PI.

(a-1-4) Cross-Sectional Structure of Memory Cell Array

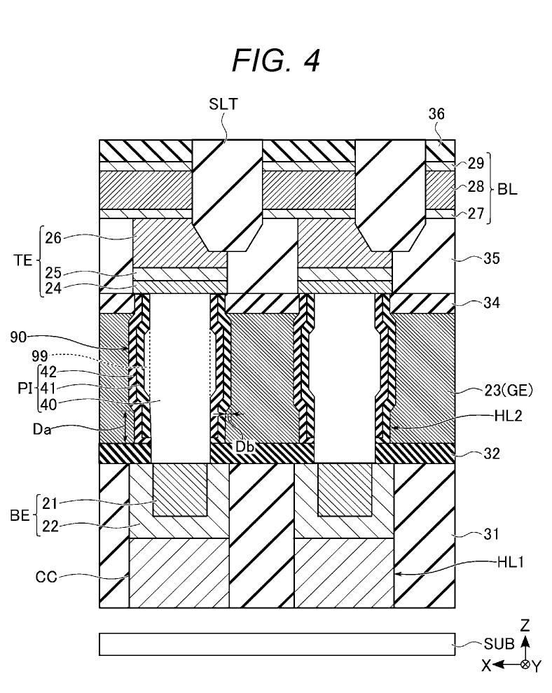

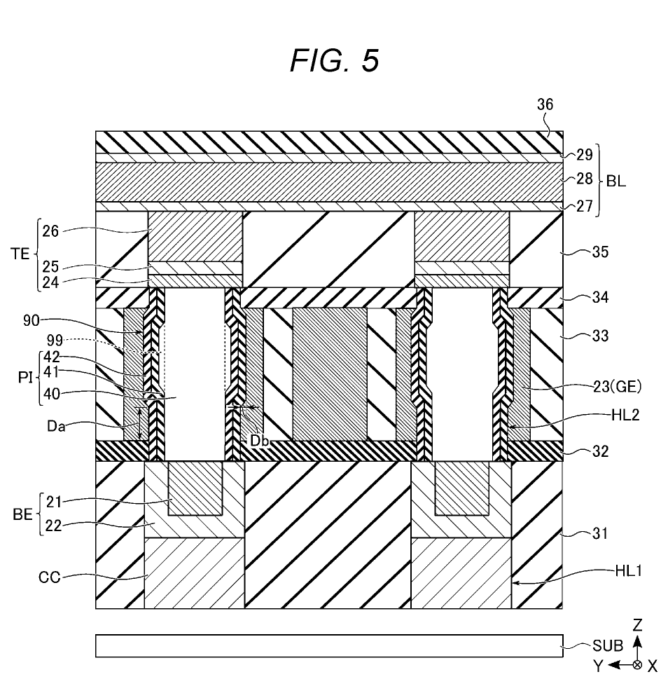

A cross-sectional structure of the memory cell array 11 of the semiconductor device 1 according to the present embodiment will be described using FIGS. 4 and 5. FIG. 4 is a cross-sectional diagram illustrating a cross section taken along a line IV-IV of FIG. 3 illustrating an example of the cross-sectional structure of the memory cell array 11 of the semiconductor device 1 according to the present embodiment. FIG. 5 is a cross-sectional diagram illustrating a cross section taken along a line V-V of FIG. 3 illustrating the example of the cross-sectional structure of the memory cell array 11 of the semiconductor device 1 according to the present embodiment.

The memory cell array 11 includes a plurality of conductors 21 to 29, insulators 31 to 36, a plurality of oxide semiconductors 40, a plurality of gate insulating films 41 and 42, and a member SLT.

The insulator 31 is provided over the substrate SUB.

An electrode of the first end of each of the plurality of cell capacitors CC is provided to overlap at least a part of the insulator 31 in the Z direction. Hereinafter, the electrode of the first end of the cell capacitor CC will also be simply referred to as the cell capacitor CC. The plurality of cell capacitors CC include a conductive material. The material includes, for example, silicon (Si). An example of the material is, for example, silicon-germanium. The cell capacitor CC has, for example, a pillar shape extending in the Z direction. A shape of an XY cross-section of the pillar-shaped cell capacitor CC may be, for example, a circular shape (or an elliptical shape) or may be a polygonal shape (for example, a quadrangular shape).

The plurality of conductors 21 are provided over the plurality of cell capacitors CC to correspond to the plurality of cell capacitors CC. The conductor 21 overlaps at least a part of the insulator 31 in the Z direction. The conductor 21 includes, for example, a conductive oxide. The plurality of conductors 21 include, for example, at least one metal element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo) and oxygen (O). The conductor 21 includes, for example, indium (In), tin (Sn), and oxygen (O). The conductor 21 includes, for example, indium tin oxide (ITO).

The plurality of conductors 22 are provided on lower surfaces of the conductors 21 and side surfaces of the conductors 21, respectively. A lower surface of the conductor 22 is in contact with an upper surface of the cell capacitor CC corresponding to the conductor 22.

For example, upper surfaces of the plurality of conductors 21 and 22 are aligned with an upper surface of the insulator 31. A set including the conductors 21 and 22 corresponding to each other functions as a lower electrode BE.

The insulator 32, the insulator 33, and the insulator 34 are provided in this order toward the upper side on the upper surface of the insulator 31 and the upper surfaces of the plurality of conductors 21 and 22.

The cell transistor is a vertical transistor including the oxide semiconductor 40 as the channel region.

Each of the plurality of oxide semiconductors 40 has a pillar-shaped structure. The plurality of oxide semiconductors 40 are provided corresponding to a plurality of lower electrodes BE (conductors 21 and 22). The oxide semiconductor 40 is provided on the upper surface of the conductor 21. A lower surface of the oxide semiconductor 40 is in contact with the upper surface of the conductor 21. The oxide semiconductors 40 penetrates the insulators 32, 33, and 34. The oxide semiconductor 40 includes, for example, at least one element among indium (In), gallium (Ga), zinc (Zn), aluminum (Al), and tin (Sn). The oxide semiconductor 40 includes, for example, at least one element among indium (In), gallium (Ga), silicon (Si), aluminum (Al), and tin (Sn), and zinc (Zn). The oxide semiconductor 40 includes, for example, indium-gallium-zinc oxide.

With the above-described configuration, the conductor 21 corresponding to the oxide semiconductor 40 is provided between the oxide semiconductor 40 and the conductor 22 arranged in the Z direction. In the above-described configuration, the conductor 21 can reduce a contact resistance between the conductor 22 and the oxide semiconductor 40.

The gate insulating films 41 and 42 are provided on a side surface of each of the oxide semiconductors 40. Each of the gate insulating films 41 and 42 has a cylindrical structure.

The gate insulating film 41 is provided on at least a part of the side surface of the oxide semiconductor 40. The gate insulating film 41 includes an insulator. The gate insulating film 41 includes, for example, silicon oxide, silicon oxynitride, a metal oxide, or a metal oxynitride. The metal in the metal oxide or the metal oxynitride used for the gate insulating film 41 is, for example, at least one element among aluminum (Al), hafnium (Hf), and zirconium (Zr).

The gate insulating film 42 is provided to cover the side surface of the gate insulating film 41. The gate insulating film 42 is provided between the gate insulating film 41 and a conductor 23. The gate insulating film 42 includes an insulator. The gate insulating film 42 includes, for example, silicon nitride, a metal oxide, a metal nitride, or a metal oxynitride. The metal element in the metal oxide, the metal nitride, or the metal oxynitride used for the gate insulating film 42 is, for example, at least one element among aluminum (Al), hafnium (Hf), and zirconium (Zr). The gate insulating film 42 is a single-layer film including one layer including silicon nitride, a metal oxide, a metal nitride, or a metal oxynitride. Alternatively, the gate insulating film 42 may also be a stacked film including two or more among silicon nitride, a metal oxide, a metal nitride, and a metal oxynitride. In the embodiment, the structure where the two gate insulating films 41 and 42 are provided is described. However, the gate insulating film 42 does not need to be provided.

A dimension (film thickness) of the gate insulating films 41 and 42 in the X direction or the Y direction is, for example, 2 nanometers (nm) or more and 10 nanometers or less.

A set including the oxide semiconductor 40 and the gate insulating films 41 and 42 corresponding to each other functions as the pillar PI. The oxide semiconductor 40 corresponds to a semiconductor forming a part (channel region) of the cell transistor CT. For example, upper surfaces of the plurality of oxide semiconductors 40 and upper surfaces of the plurality of gate insulating films 41 and 42 are aligned with an upper surface of the insulator 34.

The pillar PI is provided in a hole HL2 formed in the conductor 23. The pillar PI may have a taper shape. For example, in the pillar PI having a taper shape, a dimension of an upper portion of the pillar PI in the X direction (or the Y direction) is larger than a dimension of a lower portion of the pillar PI in the X direction (or the Y direction). The pillar PI may have a bowing shape where a center portion in the Z direction swells.

The plurality of conductors 23 are provided to overlap at least a part of the insulator 33 in the Z direction. The conductor 23 is a wiring layer (conductive layer) that functions as the gate electrode GE and the word line WL. Each of the plurality of conductors 23 extends in the X direction to correspond to the gate electrode GE. As a result, in a XZ cross-section illustrated in FIG. 4, one conductor 23 is in contact with the side surfaces of the plurality of pillars PI arranged in the X direction. The plurality of conductors 23 are arranged in the Y direction to correspond to the plurality of gate electrodes GE. As a result, in a YZ cross-section illustrated in FIG. 5, the conductor 23 is in contact with the side surface of one pillar PI. The conductor 23 includes, for example, tungsten (W) or titanium (Ti). Hereinafter, the conductor 23 will also be referred to as a wiring layer 23.

A dimension (film thickness) of the conductor 23 in the Z direction is, for example, 30 nm or more and 50 nm or less.

The insulator 35 is provided on the upper surface of the insulator 34, the upper surfaces of the plurality of oxide semiconductors 40, and the upper surfaces of the gate insulating films 41 and 42.

A plurality of conductors 24 are provided corresponding to the plurality of pillars PI to overlap at least a part of the insulator 35 in the Z direction. The conductor 24 is provided on the upper surface of the oxide semiconductor 40. The conductor 24 covers the upper surface of the corresponding oxide semiconductor 40. The conductor 24 includes, for example, a conductive oxide. The conductor 24 includes, for example, at least one metal element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo) and oxygen (O). The plurality of conductors 24 include, for example, an oxide of at least one element among indium (In) and tin (Sn). The conductive oxide includes, for example, at least one compound among indium tin oxide and tin oxide.

A plurality of conductors 25 are provided on upper surfaces of the plurality of conductors 24 to correspond to the plurality of conductors 24, respectively. The conductor 25 includes, for example, at least one element among titanium (Ti), tin (Sn), zinc (Zn), ruthenium (Ru), and niobium (Nb). The conductor 25 includes, for example, a nitride of at least one element among these elements. The conductor 25 includes, for example, titanium nitride (TiN).

A plurality of conductors 26 are provided on upper surfaces of the plurality of conductors 25 to correspond to the plurality of conductors 25. The conductor 26 includes, for example, tungsten (W). Upper surfaces of the plurality of conductors 26 are aligned with an upper surface of the insulator 35. In the Z direction, a film thickness of the conductor 26 is larger than, for example, a film thickness of the conductor 24 and a film thickness of the conductor 25.

In the above-described configuration, a set including the conductors 24, 25, and 26 corresponding to each other functions as the upper electrode TE. The conductor 25 is provided to prevent the metal element in the conductor 26 from penetrating into the conductor 24 by diffusion. The conductor 25 can function as, for example, barrier metal.

A plurality of conductors 27 are provided on the upper surface of the insulator 35 and the upper surfaces of the plurality of conductors 26. Each of the conductors 27 is provided on the plurality of upper electrodes TE. Each of the conductors 27 is in contact with the conductor 26 of the upper electrode TE corresponding to the conductor 27. The conductor 27 extends in the Y direction. The plurality of upper electrodes TE connected to each of the conductors 27 correspond to a plurality of bit lines BL different from each other. The plurality of conductors 27 are arranged in the X direction to correspond to the plurality of bit lines BL. The plurality of conductors 27 include, for example, titanium nitride (TiN).

A plurality of conductors 28 are provided on upper surfaces of the plurality of conductors 27, respectively. The conductor 28 includes, for example, tungsten (W).

A plurality of conductors 29 are provided on upper surfaces of the plurality of conductors 28, respectively. The conductor 29 includes, for example, titanium nitride (TiN).

In the above-described configuration, the conductors 27, 28, and 29 function as the bit lines BL. The conductor 27 and the conductor 29 are provided to prevent the metal element in the conductor 28 from penetrating into a lower layer of the conductor 27 and an upper layer of the conductor 29 by diffusion. Therefore, the conductors 27 and 29 can function as, for example, barrier metal. The conductors 27 and 29 do not need to be provided.

The insulator 36 is provided on upper surfaces of the plurality of conductors 29.

A plurality of members SLT are provided above the insulator 34. Each of the members SLT extends in the Y direction. The plurality of members SLT are arranged in the X direction. Each of the members SLT penetrates the conductors 27, 28, and 29. An upper surface of each of the members SLT is aligned with, for example, an upper surface of the insulator 36. A lower surface of each of the members SLT is in contact with, for example, the conductor 26. A lower surface of the member SLT only needs to reach a height of the upper surface of the insulator 35. The member SLT is, for example, an insulator such as silicon oxide. Two bit lines BL adjacent to each other in the X direction are separated from each other by the corresponding member SLT. The two bit lines BL are insulated from each other by the member SLT.

In a XZ cross-section including the word line WL1 or the word line WL3, the member SLT is provided to overlap, for example, a first end side of the upper electrode TE in the X direction. In a XZ cross-section including the word line WL2 or the word line WL4, each of the members SLT is provided to overlap, for example, a second end side of each of the upper electrodes TE in the X direction. In a XZ cross-section illustrated in FIG. 4, an example is illustrated where each of the members SLT is provided to overlap the second end side of the upper electrode TE corresponding to the member SLT.

In the semiconductor device 1 according to the present embodiment, the wiring layer (conductor) 23 as the word line WL and the gate electrode GE includes a recess 90 in a portion (region) facing the pillar PI. The recess 90 is provided on a part of a side surface of the wiring layer 23. For example, the recess 90 is provided on a side surface of an upper portion of the wiring layer 23. For example, the recess 90 is not provided on a side surface of a lower portion of the wiring layer 23. For example, a lower end of the recess 90 in the Z direction is positioned to be higher than a lower surface (bottom portion) of the wiring layer 23, and is positioned to be lower than a position of half of the wiring layer 23 in the Z direction. For example, an upper end of the recess 90 in the Z direction is aligned with a position of an upper portion of the wiring layer 23. For example, a dimension Da in the Z direction from the bottom portion of the wiring layer 23 to the lower end of the recess 90 is larger than a dimension (depth of the recess 90) Db of the recess 90 in the X direction or the Y direction. The depth Db of the recess 90 corresponds to a dimension from an opening (opening surface) of the recess 90 facing the pillar PI in the X direction or the Y direction of the recess 90 to a side surface of the gate electrode GE at the position of the recess 90.

In FIG. 4, a position where the dimension of the gate electrode GE in the X direction is the longest is defined as a first position, and a position where the dimension of the gate electrode GE in the X direction is the shortest is defined as a second position. For example, the dimension Da is the dimension in the Z direction from the bottom portion of the wiring layer 23 to the first position. For example, the dimension Db is the dimension in the X direction from the first position to the second position. For example, the first position defining the dimension Da is positioned to be lower than the recess 90, and is positioned on an end portion of the recess 90 on the lower electrode BE side or positioned to be lower than the end portion.

In the semiconductor device 1 according to the present embodiment, the oxide semiconductor 40 of the pillar PI includes a protrusion 99 in a portion facing the recess 90. The protrusion 99 protrudes from the side surface of the oxide semiconductor 40 in the X direction or the Y direction. The protrusion 99 may be treated as a portion of the pillar PI. A dimension of the oxide semiconductor 40 in the X direction or the Y direction is large in the protrusion 99. For example, the dimension of the oxide semiconductor 40 in the X direction or the Y direction in the protrusion 99 is larger than a dimension in the X direction or the Y direction on the lower surface of the oxide semiconductor 40.

A part of the gate insulating films 41 and 42 is bent along a shape of the recess 90 and a shape of the protrusion 99. For example, a part of the gate insulating films 41 and 42 is curved. The protrusion 99 is provided on the bent portion of the gate insulating films 41 and 42.

When the recess 90 is embedded with the gate insulating films 41 and 42 such that the gate insulating films 41 and 42 are flat, the side surface of the oxide semiconductor 40 has a flat surface not including the protrusion 99.

In the semiconductor device 1 according to the present embodiment, characteristics of the cell transistor CT can be improved by the recess 90 of the conductor 23 and the protrusion 99 of the oxide semiconductor 40.

### (b) Manufacturing Method

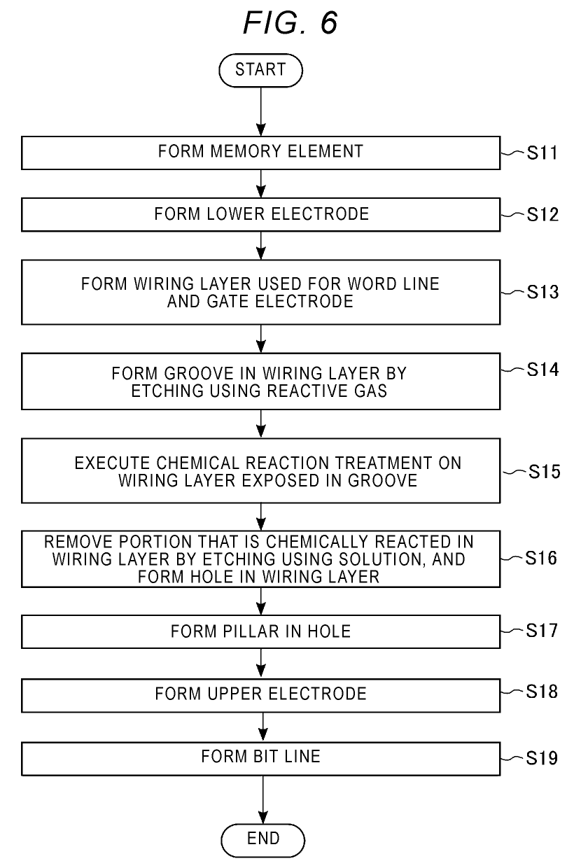

A method of manufacturing the semiconductor device 1 according to the present embodiment will be described with reference to FIGS. 6 to 13.

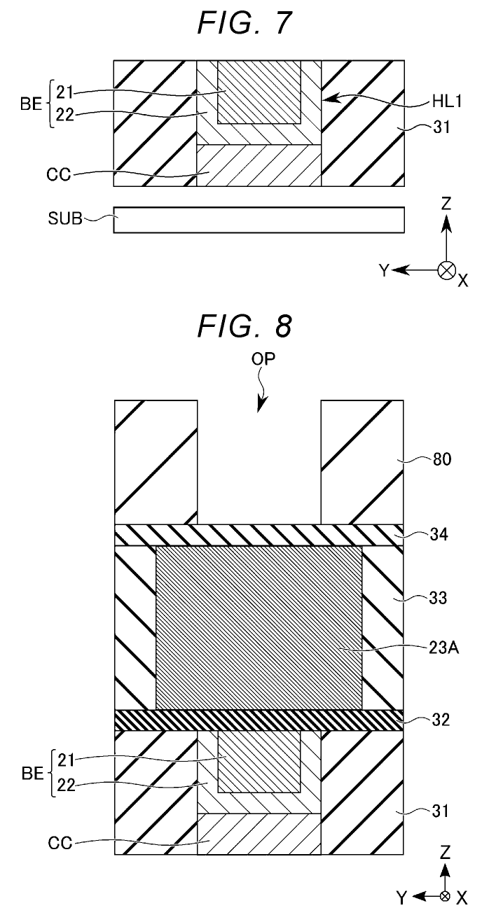

FIG. 6 is a flowchart illustrating a method of manufacturing the semiconductor device 1 according to the present embodiment. Each of FIGS. 7 to 13 is a process cross-sectional view illustrating an example of the method of manufacturing the semiconductor device 1 according to the present embodiment. The cross-sections illustrated in FIGS. 7 to 13 correspond to a cross-section taken along a YZ plane of the semiconductor device 1 according to the present embodiment. In FIGS. 7 to 13, manufacturing steps of the semiconductor device 1 are illustrated focusing on a region in which one memory cell is formed.

<S11, S12>

As illustrated in FIG. 7, the insulator 31 is formed over the substrate SUB. A plurality of memory elements CC are formed in a plurality of holes HL1 formed in the insulator 31, respectively. The memory element CC is, for example, the cell capacitor CC.

The plurality of lower electrodes BE are formed on the upper surfaces of the plurality of cell capacitors CC, respectively. For example, the conductor 22 of the lower electrode BE is formed on the upper surface of the cell capacitor CC and the side surface of the insulator 31, and subsequently the conductor 21 of the lower electrode BE is formed on the conductor 22.

<S13>

As illustrated in FIG. 8, the insulator 32 is formed on the insulator 31 and the lower electrode BE. The insulator 33 and a wiring layer 23A are formed on the insulator 32. The wiring layer 23A is processed by photolithography and etching to have a predetermined shape. The wiring layer 23A is a conductor for forming the word line WL and the gate electrode GE of the cell transistor CT. A material of the wiring layer 23A is, for example, tungsten (W) or titanium (Ti).

The insulator 34 is formed on the wiring layer 23A and the insulator 33.

A mask 80 is formed on the insulator 34. A plurality of openings OP are formed in the mask 80 by photolithography and etching. A position of the opening OP corresponds to a position of the cell transistor CT where the pillar PI is formed.

<S14>

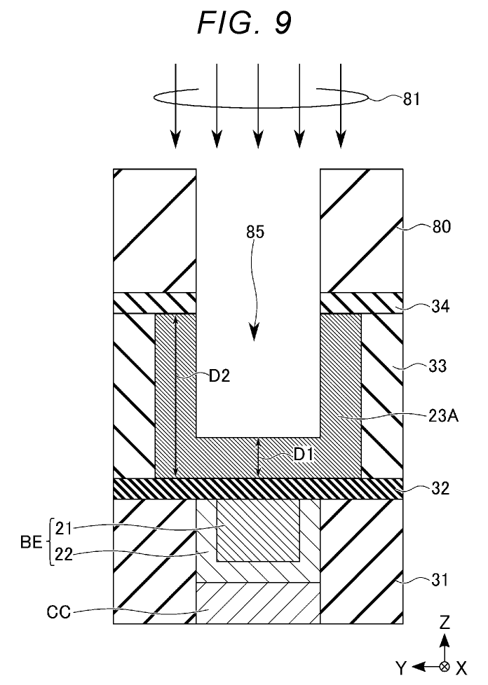

As illustrated in FIG. 9, an etching treatment such as reactive ion etching (RIE) using reactive gas (etching gas) 81 is executed on the insulator 34 and the wiring layer 23A based on a pattern of the mask 80. Hereinafter, the etching treatment using the reactive gas will also be referred to as dry etching.

The opening is formed in the insulator 34 by dry etching.

The wiring layer 23A is etched by the ionized reactive gas 81. When the wiring layer 23A includes tungsten, the reactive gas 81 is, for example, fluorine-based gas such as nitrogen trifluoride (NF₃).

Before exposing the insulator 32 below the wiring layer 23A, the dry etching on the wiring layer 23A is stopped.

In the present embodiment, a groove 85 is formed in the wiring layer 23A through the etching treatment. A film thickness D1 of the wiring layer 23A remaining below a bottom portion of the groove 85 (over the lower electrode BE) is 10% to 30% of a film thickness D2 of the wiring layer 23A between the insulator 32 and the insulator 34. For example, when the film thickness D2 of the wiring layer 23A is 30 nm to 50 nm, the film thickness D1 of the wiring layer 23A below the bottom portion of the groove 85 is 3 nm to 15 nm.

When the wiring layer 23A is a titanium layer, fluorine-based gas or chlorine-based gas is used for the reactive gas 81.

<S15>

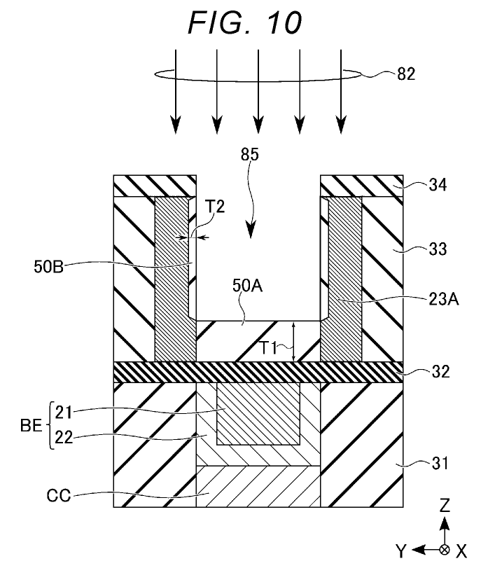

As illustrated in FIG. 10, after forming the groove 85 in the wiring layer 23A, a chemical reaction treatment on the wiring layer 23 is executed. A chemical reaction layer 50 is formed in an exposed portion of the wiring layer 23 from the groove 85. The chemical reaction layer 50 includes an oxide layer 50A and an oxide layer 50B. The chemical reaction treatment is executed using ions 82. For example, the chemical reaction treatment is executed in the same device (chamber) as that of the above-described dry etching. For example, the chemical reaction treatment is executed in a temperature control range of electrostatic chuck of a chamber. For example, the chemical reaction treatment is executed at 0°C or higher and 120°C or lower. The chemical reaction layer 50 will also be referred to as a compound layer (or simply a compound) 50.

For example, an oxidation treatment by the oxygen ions 82 is executed on the wiring layer 23A as the chemical reaction treatment. An exposed surface of the wiring layer 23A is oxidized by a chemical reaction with the oxygen ions.

Through the oxidation treatment, the oxide layers 50A and 50B are formed on the exposed surface of the wiring layer 23A. The oxide layer 50A is formed in the wiring layer 23A positioned on the bottom portion of the groove 85. The oxide layer 50B is formed in the wiring layer 23A positioned on a side portion of the groove 85. When the wiring layer 23A is tungsten, the oxide layers 50A and 50B are tungsten oxide.

For example, during the oxidation treatment, a bias is applied to the substrate SUB. Accordingly, the oxygen ions are accelerated to penetrate into the wiring layer 23A in a direction substantially perpendicular to the surface of the wiring layer 23A. Since anisotropy of oxidation is high, the oxidation amount of the wiring layer 23A of the side portion of the groove 85 is less than the oxidation amount of the wiring layer 23A of the bottom portion of the groove 85. For example, the side surface of the wiring layer 23A is mainly oxidized by radical oxidizing species. A penetration depth (diffusion distance) of radical oxygen into the wiring layer 23A depends on the temperature of the substrate SUB. That is, the oxidation amount by radical oxygen can be controlled by a temperature control of the substrate SUB. For example, by heating the substrate SUB to a high temperature, the oxidation amount of the groove 85 can be increased. In addition, on the side surface of the wiring layer 23A, an oxide on the outermost surface generated by radical oxygen functions as a layer for inhibiting penetration of oxygen, and prevents penetration of new oxygen. Accordingly, the oxidation of the side surface of the wiring layer 23A is stopped at a certain depth. In this way, the film thickness T2 of the oxide layer 50B in the Y direction or the X direction is less than the film thickness T1 of the oxide layer 50A in the Z direction.

The chemical reaction treatment on the wiring layer 23A may be a nitriding treatment using nitrogen ions. Through the nitriding treatment, nitride layers (for example, a tungsten nitride layer or titanium nitride) 50A and 50B are formed in the wiring layer 23A along a shape of the groove 85. The chemical reaction treatment may also be an oxynitriding treatment using both of oxygen ions and nitrogen ions.

<S16>

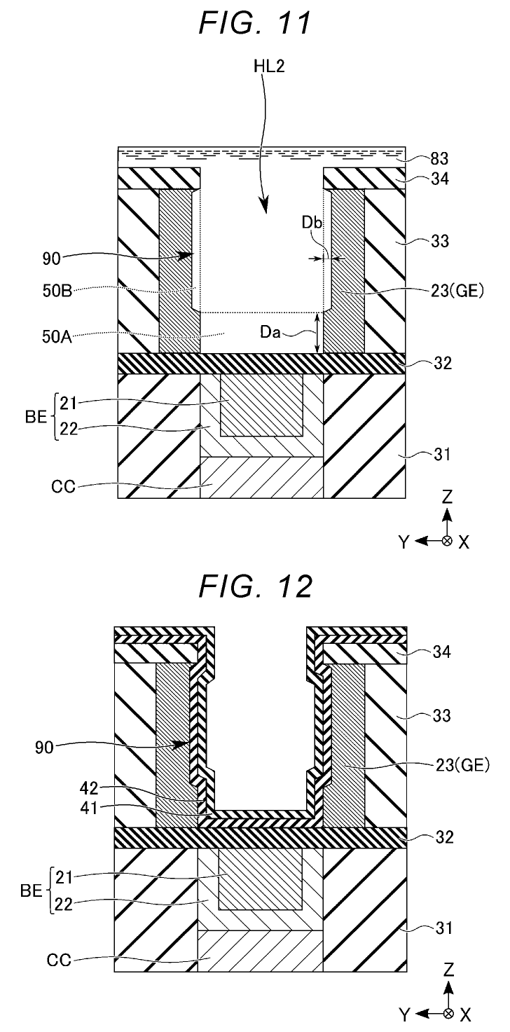

As illustrated in FIG. 11, in the present embodiment, the oxide layers 50A and 50B are selectively removed through an etching treatment using an etching solution (chemical agent) 83. Hereinafter, the etching treatment using the etching solution will be referred to as wet etching.

For example, when the oxide layers 50A and 50B are tungsten oxide layers, the solution 83 is a hydrochloric acid (HCl) or trimethyl-2-hydroxyethyl ammonium hydroxide (TMY) solution. When the oxide layers 50A and 50B are titanium oxide layers, the solution 83 is a HCl or TMY solution. When the layers 50A and 50B are tungsten nitride or titanium nitride, the HCl or TMY solution can be used as the solution 83.

By removing the oxide layer 50A, the hole HL2 is formed in the wiring layer 23. As a result, the gate electrode GE is formed in the wiring layer 23. The surface of the insulator 32 is exposed through the hole HL2. The hole HL2 is formed at a formation position of the pillar PI.

In the present embodiment, by removing the oxide layer 50B, the recess 90 is formed in the side surface of the wiring layer 23. By forming the recess 90, the side surface of the wiring layer 23 is retracted in a direction (X direction or Y direction) parallel to the surface of the substrate SUB. A lower end of the recess 90 in the Z direction is positioned to be higher than the lower surface of the wiring layer 23. The dimension Da from the lower surface of the wiring layer 23 to the lower end of the recess 90 is larger than the depth Db of the recess 90.

<S17>

The pillar PI is formed in the hole HL2 of the wiring layer 23 such that the pillar PI is electrically connected to the lower electrode BE.

As illustrated in FIG. 12, the gate insulating film 42 is formed on the side surface of the wiring layer 23 and the insulator 32. The gate insulating film 41 is formed on the gate insulating film 42.

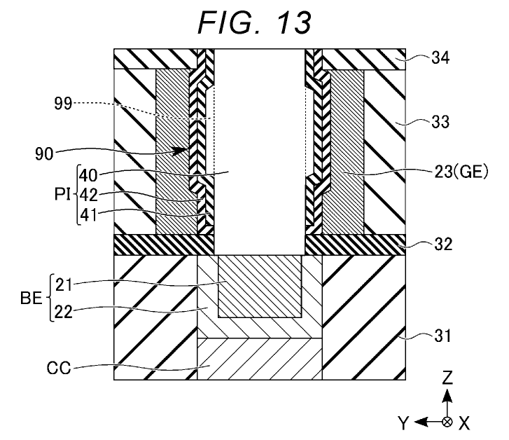

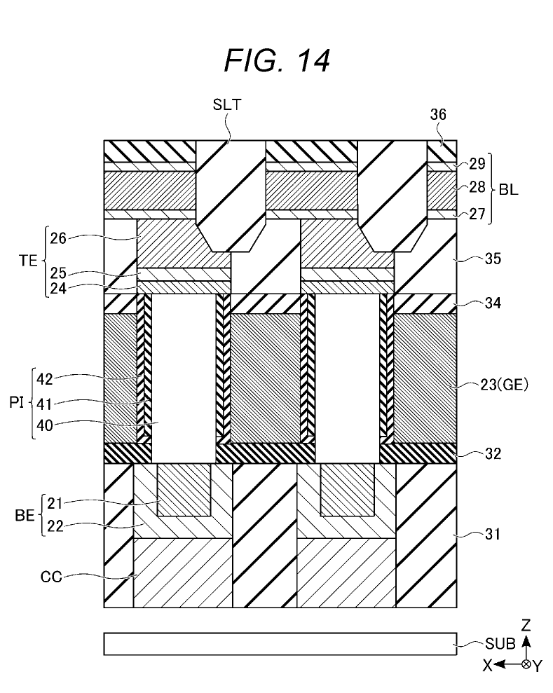

As illustrated in FIG. 13, the gate insulating films 41 and 42 and the insulator 32 are removed from the upper surface of the lower electrode BE by reactive ion etching through the hole HL2. Next, the oxide semiconductor 40 is formed on the gate insulating film 41 and the lower electrode BE. The oxide semiconductor 40 is in direct contact with the lower electrode BE.

By forming the pillar PI, the cell transistor CT is formed.

As described above, in the present embodiment, the recess 90 is formed in the side surface of the wiring layer 23. A part of the gate insulating films 41 and 42 is bent along the shape of the recess 90. The protrusion 99 is formed in the oxide semiconductor 40 to correspond to the recess 90.

In the present embodiment, the gate insulating films 41 and 42 are formed on the recess 90 of the side surface of the wiring layer 23A. The gate insulating films 41 and 42 are provided at a position retracted from the side surface of the opening of the insulator 34 in a direction parallel to the surface of the substrate SUB. A portion of the gate insulating films 41 and 42 in the recess 90 is retracted in the X direction or the Y direction from a portion of the gate insulating films 41 and 42 higher or lower than the recess 90 in the Z direction.

In FIG. 4, in the gate insulating films 41 and 42, a position closest to the upper electrode TE is defined as a third position, and a position closest to the lower electrode BE is defined as a fourth position. For example, in the Z direction, a part of the oxide semiconductor 40 is present between the third position and the fourth position.

During the etching for exposing the upper surface of the lower electrode BE, the ions of the etching gas having high anisotropy are converged in a range of the opening of the insulator 34, and are incident into the hole HL2 in the Z direction. The positions of the gate insulating films 41 and 42 are retracted in the Y direction from the opening of the insulator 34 according to the depth Db of the recess 90 in the Y direction (or the X direction). The gate insulating films 41 and 42 are formed in the recess 90. Accordingly, when the recess 90 is formed, a probability that the ions of the reactive gas collide with the gate insulating films 41 and 42 is further reduced as compared to a case where the recess 90 is not formed.

After the wet etching and before the formation of the gate insulating films 41 and 42, the insulator 32 may be removed from the upper surface of the lower electrode BE. Next, the gate insulating films 41 and 42 are formed on the side surface of the wiring layer 23 and the upper surface of the lower electrode BE. After removing the gate insulating films 41 and 42 that cover the lower electrode BE, the oxide semiconductor 40 is formed in the hole HL2 to be in contact with the lower electrode BE.

<S18, S19>

As illustrated in FIGS. 4 and 5, the conductors 24, 25, and 26 are sequentially formed on the insulator 34 and the pillar PI. The conductors 24, 25, and 26 are processed into predetermined shapes by photolithography and etching. As a result, the upper electrode TE is formed on the pillar PI.

The insulator 35 is formed on the upper electrode TE and the insulator 34 to cover the upper electrode TE. A planarization treatment such as chemical-mechanical polishing (CMP) is executed on the insulator 35 using the upper electrode TE as a stopper. As a result, the upper surface of the upper electrode TE is exposed from the insulator 35.

The conductors 27, 28, and 29 are sequentially formed on the upper electrode TE and the insulator 35. The insulator 36 is formed on the conductor 29. The conductors 24, 25, and 26 are processed into predetermined shapes by photolithography and etching. For example, a slit extending in the Y direction is formed in the insulator 36 and the conductors 27, 28, and 29 to reach the upper electrode TE. The member SLT including an insulator is embedded in the slit. As a result, the bit line BL is formed.

Through the above-described manufacturing steps, the semiconductor device 1 according to the present embodiment is completed.

### (c) Summary

In the semiconductor device 1 according to the present embodiment, the cell transistor CT includes the gate electrode GE including the recess 90 and the oxide semiconductor 40 including the protrusion 99.

As in the present embodiment, when the recess 90 is provided in the side surface facing the hole HL2 in the gate electrode GE, the gate insulating films 41 and 42 are formed on the side surface of the gate electrode GE along the recess 90 that is retracted in the direction parallel to the surface of the substrate SUB. In this case, when the member covering the upper surface of the lower electrode BE is removed through the hole HL2, a probability that the ions of the etching gas collide with the gate insulating films 41 and 42 can be reduced. As a result, in the semiconductor device 1 according to the present embodiment, damage of the gate insulating films 41 and 42 of the transistor CT can be reduced.

As a result, transistor characteristics of the semiconductor device 1 according to the present embodiment can be improved.

In addition, in the semiconductor device 1 according to the present embodiment, the recess 90 is provided on the side surface of the upper portion of the gate electrode GE, and is not provided on the side surface of the lower portion of the gate electrode GE. Accordingly, in the lower portion of the gate electrode GE, a relatively thick film thickness is maintained. As a result, in the present embodiment, a risk of disconnection of the wiring layer 23 between transistors CT adjacent to each other is reduced as compared to a case where the recess 90 is provided across the entire side surface of the gate electrode GE.

In addition, in the semiconductor device 1 according to the present embodiment, the oxide semiconductor 40 has the protrusion. Therefore, in a part of the hole HL2, the dimension of the hole HL2 in the X direction or the Y direction is large, therefore, the oxide semiconductor 40 is easily formed in the hole HL2.

In a general method of manufacturing a semiconductor device, when a hole in which a pillar of a cell transistor is embedded is formed in a wiring layer, the wiring layer is etched by executing dry etching once. Ions of reactive gas react with a member of the wiring layer such that the member is volatilized and the wiring layer is etched. Reactive gas (reactive ions) used for dry etching collides with an insulator of a lower layer of the wiring layer when a hole penetrates into the wiring layer. The reactive gas may rebound due to the insulator substantially without reacting with the insulator. When the rebounded reactive gas collides with a side surface of the wiring layer in the hole, the side surface of the wiring layer may be unintentionally etched by the rebounded reactive gas. Due to side etching of the wiring layer by the unintended etching using the rebounded reactive gas, the wiring layer may disappear from a region where formation of a gate electrode and a word line is scheduled. In this case, disconnection of the formed word line from the wiring layer or defects of the gate electrode of the cell transistor occur. As a result, the semiconductor device manufactured using the general manufacturing method is likely to be a defective product.

In the method of manufacturing the semiconductor device 1 according to the present embodiment, when the hole HL2 in which the pillar PI is embedded is formed in the wiring layer 23, the wiring layer 23 is etched through two steps. Between the first etching and the second etching, the chemical reaction layer 50 (50A, 50B) is partially formed in the wiring layer 23 through the chemical reaction treatment such as the oxidation treatment or the nitriding treatment.

The first etching step for forming the hole HL2 is dry etching having high anisotropy. As a result, the groove 85 is formed in the wiring layer 23.

The chemical reaction layers (compound) 50A and 50B are formed on the exposed portion of the wiring layer 23 along the shape of the groove 85 through the chemical reaction treatment.

The second etching step for forming the hole HL2 is wet etching. The chemical reaction layers 50A and 50B are removed by the wet etching. The chemical reaction layer 50A is selectively removed from the upper side of the lower electrode BE by the wet etching.

By removing the chemical reaction layer 50B, the recess 90 is formed on the side surface of the wiring layer 23.

In the present embodiment, the case where the dimension of the upper surface of the oxide semiconductor 40 and the dimension of the lower surface of the oxide semiconductor 40 in the X direction or the Y direction are the same is described. However, the present embodiment is not limited to this example. The dimension of the upper surface of the oxide semiconductor 40 may be less than the dimension of the lower surface of the oxide semiconductor 40, and the dimension of the upper surface of the oxide semiconductor 40 may be larger than the dimension of the lower surface of the oxide semiconductor 40.

In this way, in the method of manufacturing the semiconductor device 1 according to the present embodiment, unintended removal of the wiring layer 23 by the rebounded reactive gas is prevented. Accordingly, in the present embodiment, occurrence of a defective semiconductor device is reduced.

As a result, in the method of manufacturing the semiconductor device 1 according to the present embodiment, the manufacturing yield of semiconductor devices can be improved.

As described above, in the semiconductor device according to the present embodiment, transistor characteristics in the semiconductor device can be improved. In addition, in the method of manufacturing the semiconductor device according to the present embodiment, the quality of the semiconductor device can be improved.

(2) Second Embodiment

A semiconductor device and a method of manufacturing the semiconductor device according to a second embodiment will be described with reference to FIGS. 14 to 17.

(a) Structure

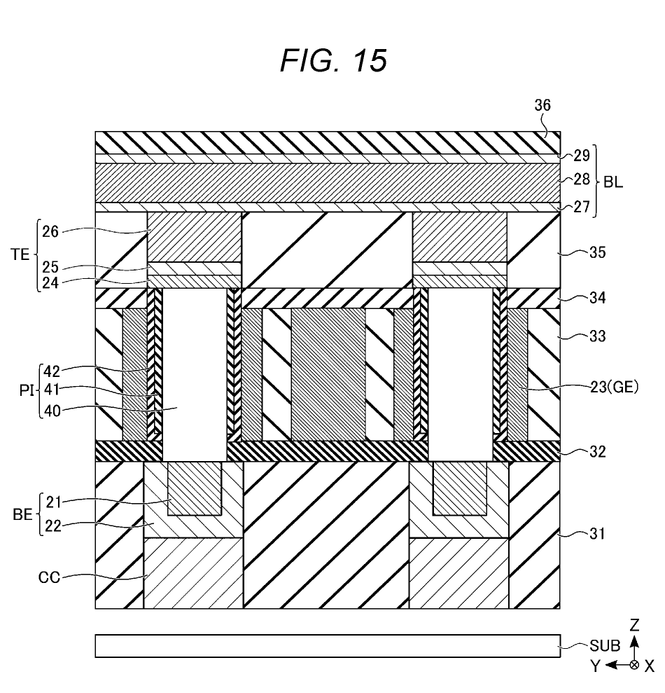

A structure of the semiconductor device 1 according to the present embodiment will be described with reference to FIGS. 14 and 15.

FIG. 14 is a cross-sectional diagram illustrating a cross section taken along an XZ plane of the memory cell array 11 illustrating an example of the cross-sectional structure of the memory cell array 11 of the semiconductor device 1 according to the present embodiment. FIG. 15 is a cross-sectional diagram illustrating a cross section taken along a YZ plane of the memory cell array 11 illustrating the example of the cross-sectional structure of the memory cell array 11 of the semiconductor device 1 according to the present embodiment.

As illustrated in FIGS. 14 and 15, in the semiconductor device 1 according to the present embodiment, the gate electrode GE of the wiring layer 23 does not include the recess. The gate electrode GE has a flat side surface. The flat side surface of the gate electrode GE faces the oxide semiconductor 40 through the gate insulating films 41 and 42.

Along a shape of the gate electrode GE not including the recess, the oxide semiconductor 40 of the pillar PI does not include the protrusion. In addition, the gate insulating films 41 and 42 are provided flat between the side surface of the gate electrode GE and the side surface of the oxide semiconductor 40 without being bent.

In the present embodiment, the case where the dimension of the upper surface of the oxide semiconductor 40 and the dimension of the lower surface of the oxide semiconductor 40 in the X direction or the Y direction are the same is described. However, the present embodiment is not limited to this example. The dimension of the upper surface of the oxide semiconductor 40 may be less than the dimension of the lower surface of the oxide semiconductor 40, and the dimension of the upper surface of the oxide semiconductor 40 may be larger than the dimension of the lower surface of the oxide semiconductor 40.

(b) Manufacturing Method

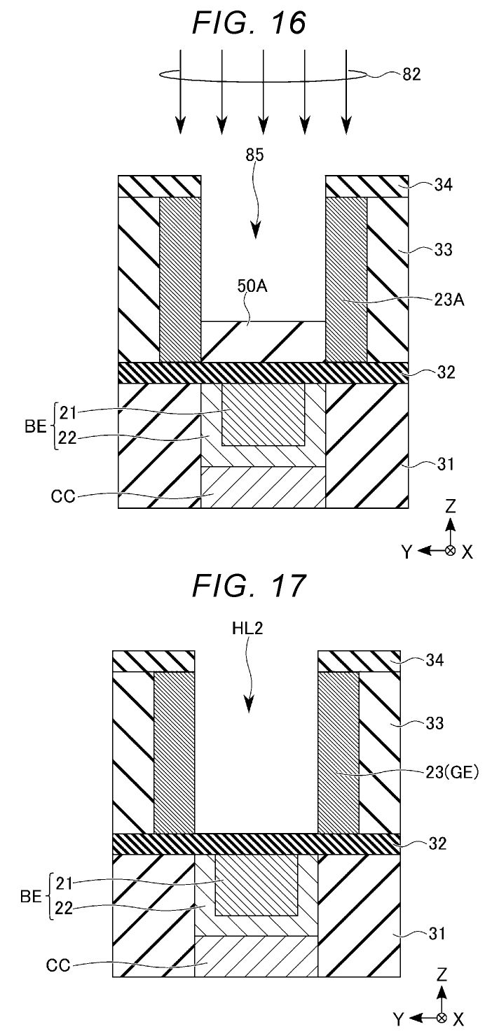

A method of manufacturing the semiconductor device 1 according to the present embodiment will be described with reference to FIGS. 16 and 17. FIGS. 16 and 17 are process cross-sectional view illustrating the method of manufacturing the semiconductor device 1 according to the present embodiment.

As illustrated in FIG. 16, the groove 85 is formed in the wiring layer 23A by dry etching through the above-described steps of FIGS. 7 to 9.

Next, the oxidation treatment using the oxygen ions 82 (or the nitriding treatment using the nitrogen ions) is executed on the wiring layer 23A exposed in the groove 85.

During the oxidation treatment using the ions 82, when the temperature of the substrate SUB (the temperature in an etching chamber) is low, occurrence of oxidizing species such as radical oxygen is prevented. In addition, penetration of oxygen into the side surface of the wiring layer 23A is prevented. Accordingly, the oxidation reaction of the side surface of the wiring layer 23A is prevented. As a result, the wiring layer 23A of the bottom portion of the groove 85 is oxidized by implanting the oxygen ions, but the wiring layer 23A of the side portion of the groove 85 is not oxidized. Accordingly, the oxide layer is not formed on the side surface of the wiring layer 23A.

As illustrated in FIG. 17, the oxide layer 50A is selectively removed by wet etching. As a result, in the present embodiment, the hole HL2 is formed in the wiring layer 23.

In the present embodiment, the oxide layer is not formed on the side surface of the wiring layer 23A. Accordingly, the etching does not occur on the side surface of the wiring layer 23A. Accordingly, the recess is not formed on the side surface of the wiring layer 23A.

Next, through the above-described steps, after the pillar PI is formed in the hole HL2 of the wiring layer 23, the upper electrode TE and the bit line BL are sequentially formed.

Through the above-described steps, the semiconductor device 1 according to the present embodiment is completed.

In the semiconductor device 1 according to the present embodiment, as in the above-described embodiment, unintended side etching of the wiring layer 23 during the hole formation in the wiring layer 23 can be prevented.

Accordingly, transistor characteristics of the semiconductor device 1 according to the present embodiment can be improved. In addition, in the method of manufacturing the semiconductor device 1 according to the present embodiment, the quality of the semiconductor device can be improved.

(3) Third Embodiment

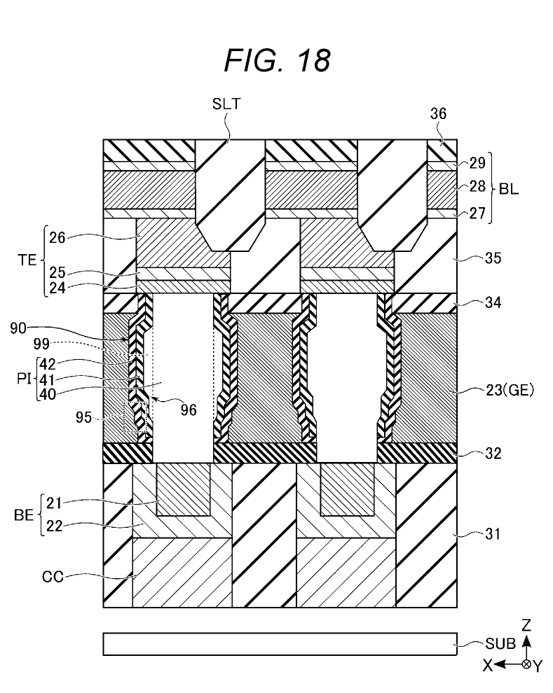

A semiconductor device and a method of manufacturing the semiconductor device according to a third embodiment will be described with reference to FIGS. 18 to 23.

(a) Structure

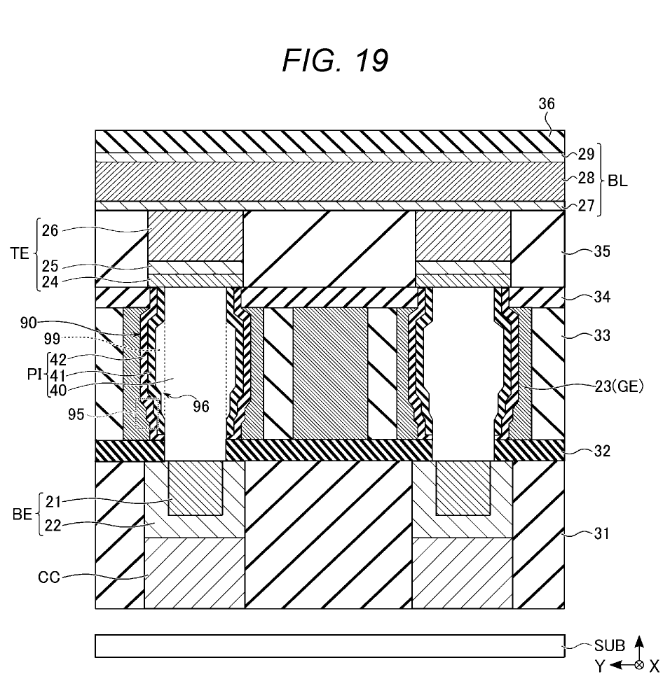

A structure of the semiconductor device 1 according to the present embodiment will be described with reference to FIGS. 18 and 19.

FIG. 18 is a cross-sectional diagram illustrating a cross section taken along an XZ plane of the memory cell array 11 illustrating an example of the cross-sectional structure of the memory cell array 11 of the semiconductor device 1 according to the present embodiment. FIG. 19 is a cross-sectional diagram illustrating a cross section taken along a YZ plane of the memory cell array 11 illustrating the example of the cross-sectional structure of the memory cell array 11 of the semiconductor device 1 according to the present embodiment.

As illustrated in FIGS. 18 and 19, in the semiconductor device 1 according to the present embodiment, a step portion 95 having two or more steps is provided on the side surface of the lower portion of the wiring layer 23 (gate electrode GE).

The recess 90 is provided on the side surface of the wiring layer 23.

In the lower portion of the recess 90 in the Z direction, the step portion 95 is provided in the wiring layer 23. The step portion 95 is a stepwise level difference.

The oxide semiconductor 40 includes a level difference 96. The level difference 96 is provided at a position corresponding to the step portion 95. For example, the level difference 96 is provided in the protrusion 99.

In the present embodiment, the gate insulating films 41 and 42 are retracted in the X direction and the Y direction from the opening of the insulator 34. Accordingly, in the present embodiment, damage caused by the collision of the ions in the gate insulating films 41 and 42 can be further reduced.

(b) Manufacturing Method

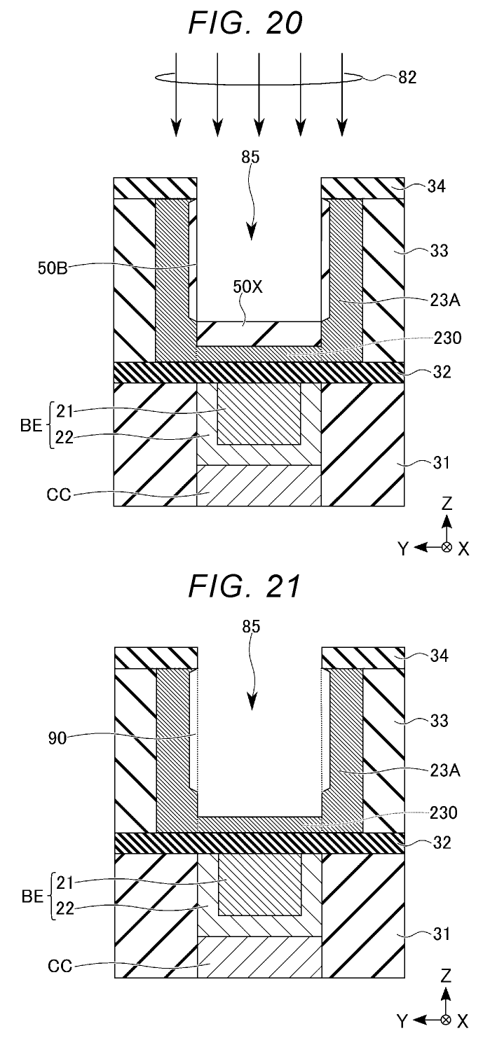

A method of manufacturing the semiconductor device 1 according to the present embodiment will be described with reference to FIGS. 20 to 23. FIGS. 20 to 23 are process cross-sectional views illustrating the method of manufacturing the semiconductor device 1 according to the present embodiment.

As illustrated in FIG. 20, the groove 85 is formed in the wiring layer 23A by dry etching through the above-described steps of FIGS. 7 to 9.

Next, the oxidation treatment using the oxygen ions 82 (or the nitriding treatment using the nitrogen ions) is executed on the wiring layer 23A exposed in the groove 85. As a result, oxide layer 50B and 50X are formed in the wiring layer 23A.

At his time, in the groove 85, the surface of the wiring layer 23A is oxidized, but a part of the bottom portion of the wiring layer 23A is not oxidized. Accordingly, a conductor 230 remains between the oxide layer 50X and the insulator 32.

As illustrated in FIG. 21, the first wet etching is executed on the oxide layers 50A and 50B in the wiring layer 23A. As a result, the oxide layers 50A and 50B are removed. The recess 90 is formed in the wiring layer 23A.

The conductor 230 on the insulator 32 is not removed by the wet etching, and thus remains.

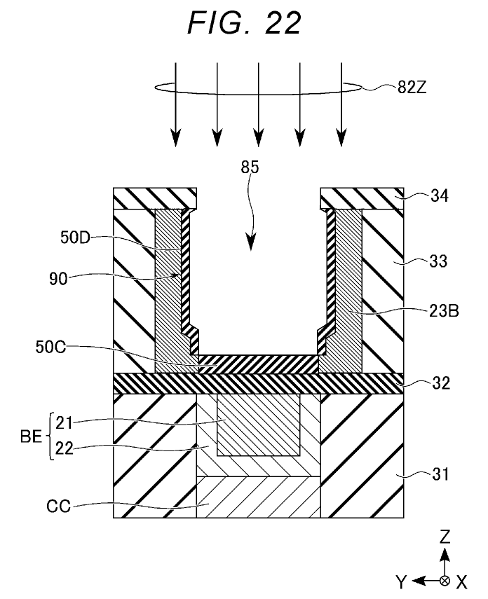

As illustrated in FIG. 22, an oxidation treatment using oxygen ions 82Z is executed again on a wiring layer 23B including the recess 90. As a result, the wiring layer 23 is partially oxidized.

An oxide layer 50C is formed on the insulator 32 by oxidizing the conductor 230. In addition, an oxide layer 50D is formed in the wiring layer 23A along the recess 90. By forming the oxide layer 50D, the side surface of the wiring layer 23A is retracted in a direction parallel to the surface of the substrate SUB.

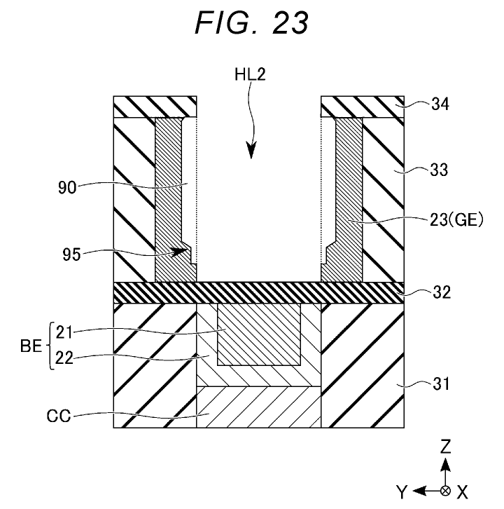

As illustrated in FIG. 23, the second wet etching is executed on the oxide layers 50C and 50D formed by the second oxidation treatment. The oxide layers 50C and 50D are removed by the wet etching. As a result, the hole HL2 is formed in the wiring layer 23.

On the side surface of the wiring layer 23 in the hole HL2, a level difference is generated between the target portion of the first wet etching and the target portion of the second wet etching. As a result, the stepwise level difference (step portion) 95 is formed on the lower portion of the side surface of the wiring layer 23.

Next, through the above-described steps, after the pillar PI is formed in the hole HL2 of the wiring layer 23, the upper electrode TE and the bit line BL are sequentially formed. According to the step portion 95 of the wiring layer 23, the level difference 96 is formed on the lower portion of the side surface of the oxide semiconductor 40 of the pillar PI.

Through the above-described steps, the semiconductor device 1 according to the present embodiment is completed.

According to the film thickness of the conductor 230 remaining on the insulator 32, the number of process cycles including the single chemical reaction treatment and the single wet etching may be three or more. Accordingly, the number of level differences in the step portion 95 increases.

In the semiconductor device 1 according to the present embodiment, as in the above-described embodiment, unintended side etching of the wiring layer 23 during the hole formation in the wiring layer 23 can be prevented.

Accordingly, in the semiconductor device 1 according to the present embodiment, transistor characteristics in the semiconductor device can be improved. In addition, in the method of manufacturing the semiconductor device 1 according to the present embodiment, the quality of the semiconductor device can be improved.

(4) Others

In the semiconductor device 1 according to the above-described embodiments, the example of the memory device where the capacitor CC is used as the memory element is described. However, an element other than a capacitor may also be used as the memory element as long as it is an element capable of storing data. For example, the memory element may be a magnetoresistive effect element, a variable resistance element, a ferroelectric element, or a phase-change element.

In addition, in the above-described embodiments, the example where the semiconductor device 1 is the memory device is described. However, the semiconductor device 1 according to the present disclosure may be a device other than a memory device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a second electrode provided above the first electrode in a first direction perpendicular to a surface of the first electrode;
an oxide semiconductor having a first end in contact with the first electrode and a second end in contact with the second electrode and extending in the first direction;
a gate insulating film provided next to a side surface of the oxide semiconductor; and
a gate electrode provided next to a side surface of the gate insulating film,
wherein the gate electrode includes a recess provided on a surface facing the oxide semiconductor.

2. The semiconductor device according to claim 1, wherein the oxide semiconductor includes a protrusion protruding in a second direction perpendicular to the first direction and facing the recess.

3. The semiconductor device according to claim 1, wherein the gate electrode includes a step portion having two or more steps provided on the first electrode side of the recess.

4. The semiconductor device according to claim 1, wherein
the gate electrode includes a bottom surface on the first electrode side and an upper surface on the second electrode side, and
a first end of the recess on the first electrode side is positioned to be higher than the bottom surface.

5. The semiconductor device according to claim 4, wherein a first dimension from the bottom surface to the first end of the recess on the first electrode side is larger than a second dimension from an opening surface of the recess to a side surface of the gate electrode in a second direction perpendicular to the first direction.

6. The semiconductor device according to claim 1, wherein a position of the gate insulating film in the recess is retracted in a second direction perpendicular to the first direction from a position of the gate insulating film higher than the recess in the first direction.

7. The semiconductor device according to claim 1, wherein the oxide semiconductor includes at least one element selected from a group including indium, gallium, silicon, aluminum, and tin, zinc, and oxygen.

8. The semiconductor device according to claim 1, further comprising:
a memory element provided below the first electrode in the first direction and electrically connected to the oxide semiconductor via the first electrode;
a word line electrically connected to the gate electrode; and
a bit line provided over the second electrode in the first direction and electrically connected to the second electrode.

9. A method of manufacturing a semiconductor device, the method comprising:
forming a wiring layer on a first insulator on a first electrode;
etching a part of the wiring layer by first etching using reactive gas to form a groove;
executing a first chemical reaction treatment on the wiring layer through the groove to form a first chemical reaction layer in a first portion positioned in a bottom portion of the groove in the wiring layer;
removing the first chemical reaction layer by second etching using a solution to form a hole in the wiring layer;
forming a pillar including a gate insulating film and a channel in the hole; and
forming a second electrode above the pillar.

10. The method according to claim 9, further comprising:
forming a second chemical reaction layer through the first chemical reaction treatment in a second portion positioned on a side portion of the groove in the wiring layer;
removing the second chemical reaction layer by the second etching to form a recess on a side surface of the wiring layer, wherein
the gate insulating film is formed on the side surface of the wiring layer, and
the channel has a protrusion facing the recess on the gate insulating film.

11. The method according to claim 10, wherein
the wiring layer includes a bottom surface on the first electrode side and an upper surface on the second electrode side, and
a first end of the recess on the first electrode side is positioned to be higher than the bottom surface of the wiring layer.

12. The method according to claim 11, wherein a first dimension from the bottom surface to the first end of the recess on the first electrode side is larger than a second dimension from an opening surface of the recess in a second direction parallel to a surface of the first electrode of the recess to the side surface of the wiring layer.

13. The method according to claim 9, further comprising:
executing, after the removal of the first chemical reaction layer, a second chemical reaction treatment to form a third chemical reaction layer in a third portion of the wiring layer remaining on the first insulator; and
removing the third chemical reaction layer by third etching using the solution.

14. The method according to claim 13, further comprising:
forming a second chemical reaction layer through the first chemical reaction treatment in a second portion positioned on a side portion of the groove in the wiring layer;
removing the second chemical reaction layer by the second etching to form a recess on a side surface of the wiring layer;
forming a fourth chemical reaction layer through the second chemical reaction treatment in a fourth portion corresponding to the recess in the wiring layer; and
removing the fourth chemical reaction layer by third etching.

15. The method according to claim 14, wherein a step portion having two or more steps is formed on the first electrode side of the wiring layer.

16. The method according to claim 9, wherein the wiring layer includes tungsten or titanium.

17. The method according to claim 16, wherein the reactive gas is fluorine-based gas.

18. The method according to claim 9, wherein the first chemical reaction treatment is a treatment using an oxygen ion or a nitride ion.

19. The method according to claim 9, wherein when the first chemical reaction layer includes a tungsten compound or a titanium compound, the solution is a hydrochloric acid or trimethyl-2-hydroxyethyl ammonium hydroxide solution.

20. The method according to claim 9, further comprising:
forming a memory element electrically connected to the first electrode before forming the first electrode;
forming the hole in the wiring layer by the first and second etching and forming a gate electrode and a word line connected to the gate electrode in the wiring layer; and
forming a bit line electrically connected to the second electrode over the second electrode.

21. The method according to claim 9, wherein
the channel includes an oxide semiconductor; and
the oxide semiconductor includes at least one element selected from the group including indium, gallium, silicon, aluminum, and tin, zinc, and oxygen.
